(19) United States
(12) Patent Application Publication
(10) Pub. No.: US 2025/0220989 A1
(43) Pub. Date: Jul. 3, 2025

(54) FINFET DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US); Randy L. Yach, Phoenix, AZ (US)

(73) Assignee: Microchip Technology Incorporated, Chandler, AZ (US)

(21) Appl. No.: 18/883,603

(22) Filed: Sep. 12, 2024

Related U.S. Application Data
(60) Provisional application No. 63/615,336, filed on Dec. 28, 2023.

(51) Int. Cl. H01L 29/06; H01L 29/66; H01L 29/78

(52) U.S. Cl. CPC H10D 62/117; H10D 30/024; H10D 30/6211; H10D 62/102

(57) ABSTRACT

A FinFET device that may include a substrate. A drain layer on a first side of the substrate. A drift layer on a second side of the substrate. The drift layer having a fin-shaped portion and a recessed portion. A doped-well layer over the recessed portion of the drift layer and along sides of the fin-shaped portion of the drift layer. A body layer and a source layer formed over a portion of the doped-well layer over the recessed portion of the drift layer. An insulating layer over the doped-well layer. A gate electrode over the insulating layer.

### CROSS-REFERENCE TO RELATED APPLICATION

The present application claims priority to U.S. Provisional Patent Application No. 63/615,336, filed on Dec. 28, 2023, the contents of which are hereby incorporated by reference in their entirety.

### TECHNICAL FIELD

The present disclosure relates to metal oxide semiconductor field-effect transistors (MOSFETs), and more specifically to FinFETs and methods for manufacturing same to increase the amount of current in a smaller die size FinFET.

### SUMMARY

According to an aspect of one or more examples, there may be provided a FinFET device that may include a substrate, a drain layer formed within the substrate at a first side of the substrate, a drift layer on a second side of the substrate, the drift layer having a fin-shaped portion and a recessed portion, a doped-well layer over the recessed portion of the drift layer and along sides of the fin-shaped portion of the drift layer, a body layer formed over a portion of the doped-well layer over the recessed portion of the drift layer, a source layer formed over a portion of the doped-well layer over the recessed portion of the drift layer, an insulating layer over a top portion of the fin-shaped portion of the drift layer, over a portion of the doped-well layer along the sides of the fin-shaped portion of the drift layer, and over a portion of the source layer, and a gate electrode over the insulating layer. The substrate may comprise bulk gallium nitride, diamond, silicon carbide, aluminum nitride, or silicon. The drain layer may comprise a first concentration of the first type dopant. The drift layer may comprise a second concentration of the first type dopant, the first concentration may be greater than the second concentration. The doped-well layer may comprise a third concentration of a second type dopant. The body layer may comprise a fourth concentration of the second type dopant. The source layer may comprise a fifth concentration of the first type dopant, the fifth concentration may be greater than the second concentration. The insulating layer may comprise silicon nitride, silicon dioxide or a mixture of silicon nitride and silicon dioxide. The first type dopant may comprise an n-type dopant and the second type dopant may comprise a p-type dopant. The first type dopant may comprise a p-type dopant and the second type dopant may comprise an n-type dopant.

According to an aspect of one or more examples, there may be provided a method for fabricating a FinFET device that may include providing a substrate, forming a drain layer within the substrate at a first side of the substrate, forming a drift layer on a second side of the substrate, the drift layer having a fin-shaped portion and a recessed portion, forming a doped-well layer over the recessed portion of the drift layer and along sides of the fin-shaped portion of the drift layer, forming a body layer over a portion of the doped-well layer over the recessed portion of the drift layer, forming a source layer over a portion of the doped-well layer over the recessed portion of the drift layer, forming an insulating layer over a top portion of the fin-shaped portion of the drift layer, over a portion of the doped-well layer along the sides of the fin-shaped portion of the drift layer, and over a portion of the source layer, and forming a gate electrode over the insulating layer. The substrate may comprise bulk gallium nitride, diamond, silicon carbide, aluminum nitride, or silicon. The drain layer may comprise a first concentration of the first type dopant. The drift layer may comprise a second concentration of the first type dopant, the first concentration may be greater than the second concentration. The doped-well layer may comprise a third concentration of a second type dopant. The body layer may comprise a fourth concentration of the second type dopant. The source layer may comprise a fifth concentration of the first type dopant, the fifth concentration may be greater than the second concentration. The insulating layer may comprise silicon nitride, silicon dioxide or a mixture of silicon nitride and silicon dioxide. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 is a cross sectional view of a FinFET device according to one or more examples;

FIG. 2A is cross sectional view of some of the steps in a method of manufacturing a FinFET device according to one or more examples;

FIG. 2B is cross sectional view of some of the steps in a method of manufacturing a FinFET device according to one or more examples;

FIG. 2C is cross sectional view of some of the steps in a method of manufacturing a FinFET device according to one or more examples;

FIG. 2D is cross sectional view of some of the steps in a method of manufacturing a FinFET device according to one or more examples; and

FIG. 2E is cross sectional view of some of the steps in a method of manufacturing a FinFET device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

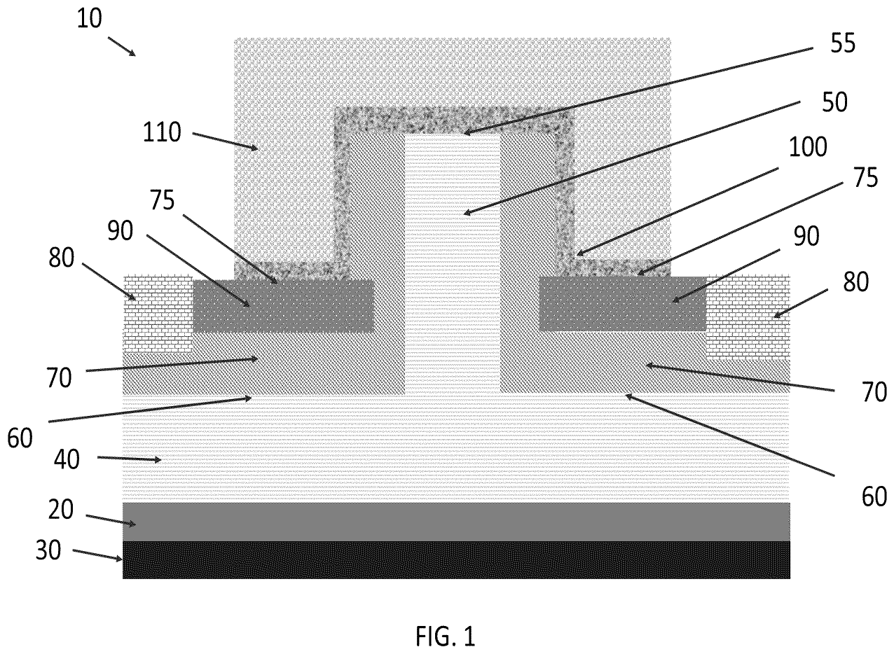

FIG. 1 shows an illustration of a FinFET device 10 according to one or more examples. As shown in FIG. 1, the FinFET device 10 may include a drain layer 30 that may have a first concentration of a first type dopant that may be on a first side of a substrate 20. The substrate 20 may comprise bulk gallium nitride, diamond, silicon carbide, sapphire, aluminum nitride, or silicon. In FIG. 1, the example FinFET device 10 may include a drift layer 40 formed on a second side of the substrate 20, the second side opposite the first side. The drift layer 40 may be formed with a fin-shaped portion 50 and recessed portions 60. The drift layer 40 may have a second concentration of the first type dopant. The first concentration of the first type dopant in the drain layer 30 may be greater than the second concentration of the first type dopant in the drift layer 40. In FIG. 1, the example FinFET device 10 may include a doped-well layer 70 formed over the recessed portions 60 of the drift layer 40. The doped-well layer 70 may have a third concentration of a second type dopant. In FIG. 1, the example FinFET device 10 may include a body layer 80 (this can be a body connection, a body extension or even a well connection) formed over a portion of the doped-well layer 70 over the recessed portion 60 of the drift layer 40. The body layer 80 may comprise a fourth concentration of the second type dopant which may include forming a recess 75 into the doped-well layer 70 while leaving doped-well layer 70 on the fin-shaped portion 50 and the recessed portions 60 of the drift layer 40. In FIG. 1, the example FinFET device 10 may include a source layer 90 formed over a portion of the doped-well layer 70 which may be over the recessed portion 60 of the drift layer 40. The source layer 90 may comprise a fifth concentration of the first type dopant wherein the fifth concentration of the source layer 90 may be greater than the second concentration of the drift layer 40. The source layer 90 may be adjacent to the body layer 80. In FIG. 1, the example FinFET device 10 may include an insulating layer 100 formed over a top portion 55 of the fin-shaped portion 50 of the drift layer 40, over a portion of the doped-well layer 70 along the sides of the fin-shaped portion 50 of the drift layer 40 and over a portion of the source layer 90. The insulating layer 100 may comprise silicon nitride, silicon dioxide or a mixture of silicon nitride and silicon dioxide. In FIG. 1, the example FinFET device 10 may include a gate electrode 110 formed over the insulating layer 100.

In the example FinFET device 10 of FIG. 1, the first type dopant may be an n-type dopant with the second type dopant being a p-type dopant. Alternatively, the first type dopant may be a p-type dopant with the second type dopant being an n-type dopant.

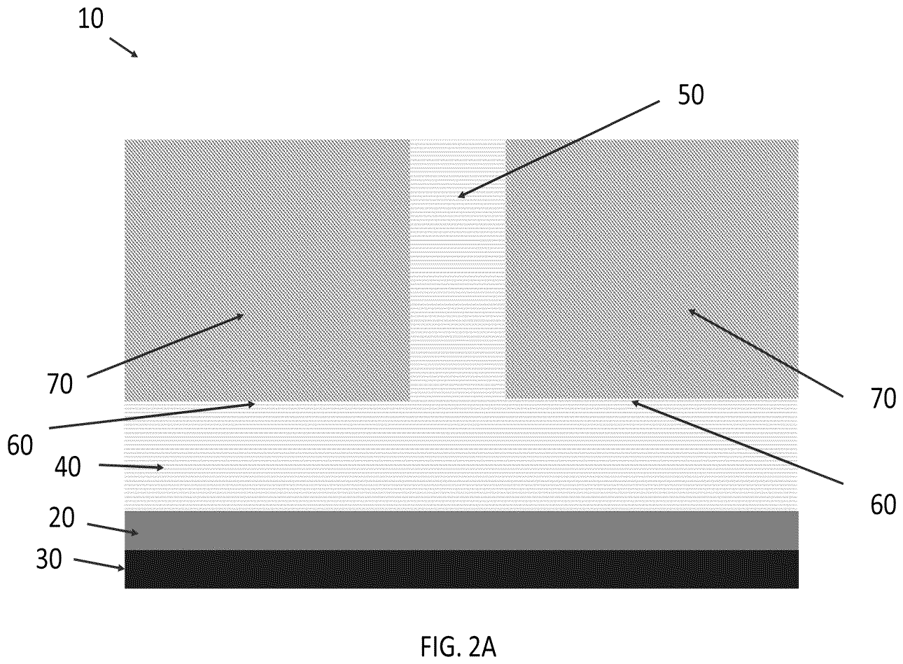

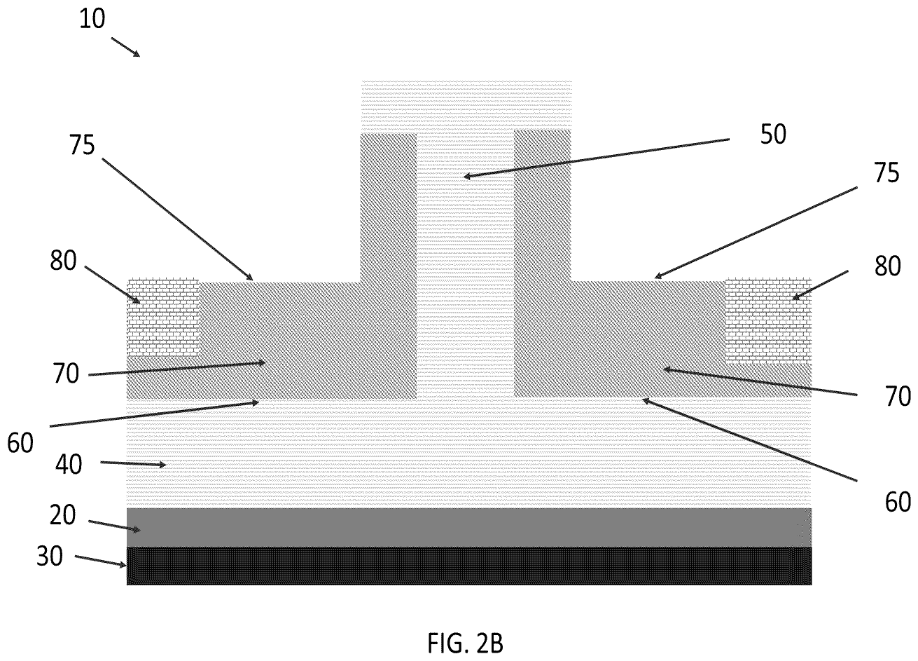

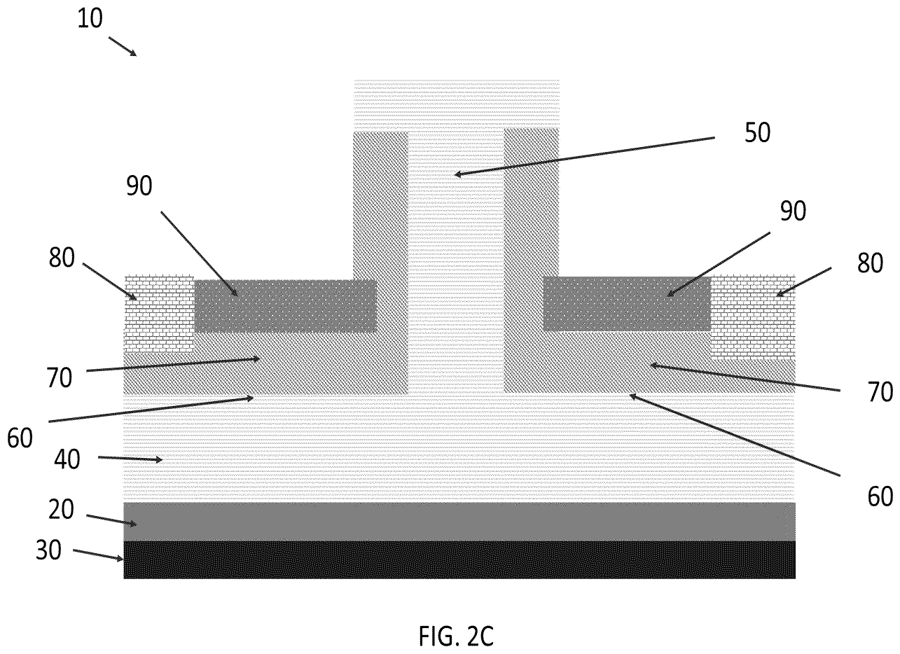

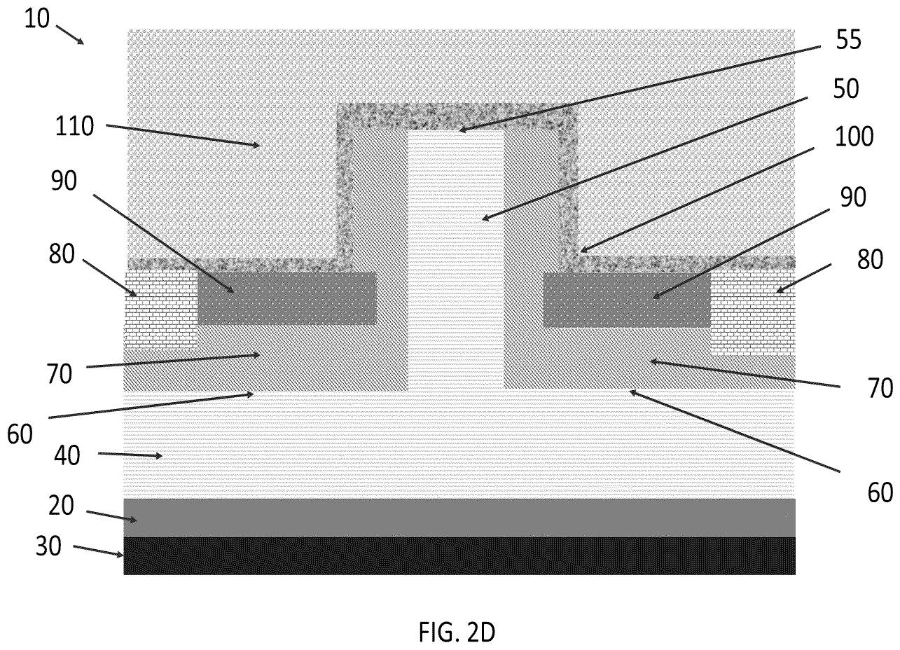

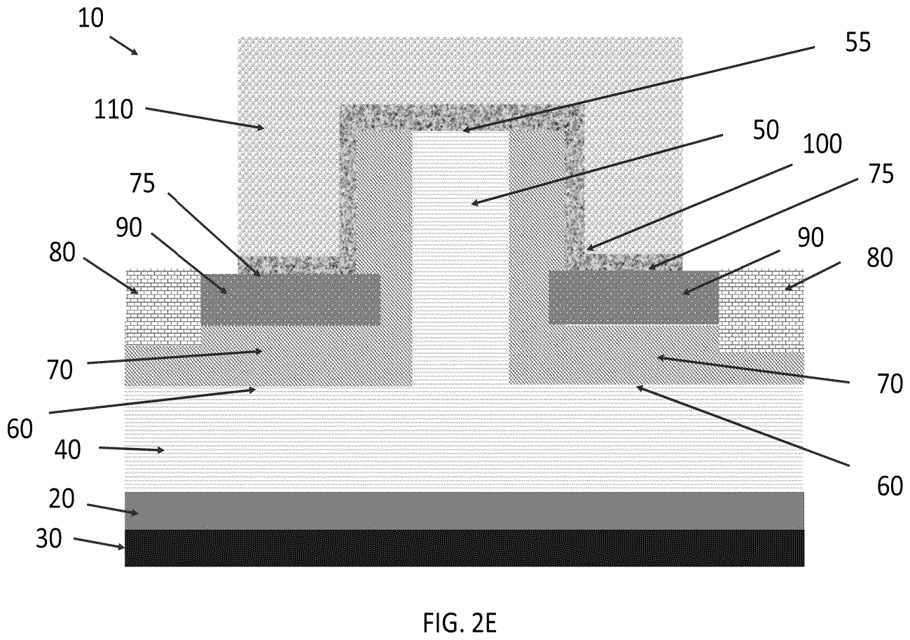

FIGS. 2A-2E is cross sectional view of some of the steps in a method of manufacturing a FinFET device 10 according to one or more examples. Although the example method shown in FIGS. 2A-2E includes steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is cross sectional view of some of the steps in a method of manufacturing a FinFET device 10 according to one or more examples. In FIG. 2A, the example method may include forming a drain layer 30 that may have a first concentration of a first type dopant that may be on a first side of a substrate 20. The substrate 20 may comprise bulk gallium nitride, diamond, silicon carbide, sapphire, aluminum nitride, or silicon. In FIG. 2A, the example method may include forming a drift layer 40 on a second side of the substrate 20, the second side opposite the first side. The drift layer 40 may be formed with a fin-shaped portion 50 and recessed portions 60. The drift layer 40 may have a second concentration of the first type dopant. The first concentration of the first type dopant in the drain layer 30 may be greater than the second concentration of the first type dopant in the drift layer 40. In FIG. 2A, the example method may include forming a doped-well layer 70 over the recessed portions 60 of the drift layer 40. The doped-well layer 70 may have a third concentration of a second type dopant.

FIG. 2B is cross sectional view of some of the steps in a method of manufacturing a FinFET device 10 according to one or more examples. In FIG. 2B, the example method may include forming a recess 75 into the doped-well layer 70 while leaving doped-well layer 70 on the fin-shaped portion 50 and the recessed portions 60 of the drift layer 40. In FIG. 2B, the example method may include forming a body 80 over a portion of the doped-well layer 70 over the recessed portion 60 of the drift layer 40. The body layer 80 may comprise a fourth concentration of the second type dopant.

[symbol]

FIG. 2C is cross sectional view of some of the steps in a method of manufacturing a FinFET device 10 according to one or more examples. In FIG. 2C, the example method may include forming a source layer 90 over a portion of the doped-well layer 70 which may be over the recessed portion 60 of the drift layer 40. The source layer 90 may comprise a fifth concentration of the first type dopant wherein the fifth concentration of the source layer 90 may be greater than the second concentration of the drift layer 40. The source layer 90 may be adjacent to the body layer 80.

FIG. 2D is cross sectional view of some of the steps in a method of manufacturing a FinFET device 10 according to one or more examples. In FIG. 2D, the example method may include forming an insulating layer 100 over a top portion 55 of the fin-shaped portion 50 of the drift layer 40, over a portion of the doped-well layer 70 along the sides of the fin-shaped portion 50 of the drift layer 40, over the source layer 90 and over the body layer 80. The insulating layer 100 may comprise silicon dioxide, silicon nitride or a mixture of silicon nitride and silicon dioxide. In FIG. 2D, the example method may include forming a gate electrode 110 over the insulating layer 100.

FIG. 2E is cross sectional view of some of the steps in a method of manufacturing a FinFET device 10 according to one or more examples. In FIG. 2E, the example method may include etching the gate electrode 110 and the insulating layer 100 such that the body layer 80 may no longer be covered by the gate electrode 110 or the insulating layer 100. In FIG. 2E, the example method may include etching the gate electrode 110 and the insulating layer 100 such that only a portion of the source layer 90 may be covered by the gate electrode 110 or the insulating layer 100.

In the example FinFET device 10 of FIGS. 2A-2E, the first type dopant may be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A FinFET device comprising:
a substrate;
a drain layer formed within the substrate at a first side of the substrate;
a drift layer on a second side of the substrate, the drift layer having a fin-shaped portion and a recessed portion;
a doped-well layer over the recessed portion of the drift layer and along sides of the fin-shaped portion of the drift layer;
a body layer formed over a portion of the doped-well layer over the recessed portion of the drift layer;
a source layer formed over a portion of the doped-well layer over the recessed portion of the drift layer;
an insulating layer over a top portion of the fin-shaped portion of the drift layer, over a portion of the doped-well layer along the sides of the fin-shaped portion of the drift layer, and over a portion of the source layer; and
a gate electrode over the insulating layer.

2. The FinFET device according to claim 1, wherein the substrate comprises bulk gallium nitride, diamond, silicon carbide, aluminum nitride, or silicon.

3. The FinFET device according to claim 1, wherein the drain layer comprises a first concentration of the first type dopant.

4. The FinFET device according to claim 3, wherein the drift layer comprises a second concentration of the first type dopant, the first concentration is greater than the second concentration.

5. The FinFET device according to claim 4, wherein the doped-well layer comprises a third concentration of a second type dopant.

6. The FinFET device according to claim 5, wherein the body layer comprises a fourth concentration of the second type dopant.

7. The FinFET device according to claim 6, wherein the source layer comprises a fifth concentration of the first type dopant, the fifth concentration is greater than the second concentration.

8. The FinFET device according to claim 7, wherein the insulating layer comprises silicon nitride, silicon dioxide or a mixture of silicon nitride and silicon dioxide.

9. The FinFET device according to claim 8, wherein the first type dopant comprises an n-type dopant and the second type dopant comprises a p-type dopant.

10. The FinFET device according to claim 8, wherein the first type dopant comprises a p-type dopant and the second type dopant comprises an n-type dopant.

11. A method for fabricating a FinFET device, comprising:
providing a substrate;
forming a drain layer within the substrate at a first side of the substrate;
forming a drift layer on a second side of the substrate, the drift layer having a fin-shaped portion and a recessed portion;
forming a doped-well layer over the recessed portion of the drift layer and along sides of the fin-shaped portion of the drift layer;
forming a body layer over a portion of the doped-well layer over the recessed portion of the drift layer;
forming a source layer over a portion of the doped-well layer over the recessed portion of the drift layer;
forming an insulating layer over a top portion of the fin-shaped portion of the drift layer, over a portion of the doped-well layer along the sides of the fin-shaped portion of the drift layer, and over a portion of the source layer; and
forming a gate electrode over the insulating layer.

12. The method for fabricating a FinFET device according to claim 11, wherein the substrate comprises bulk gallium nitride, diamond, silicon carbide, aluminum nitride, or silicon.

13. The method for fabricating a FinFET device according to claim 11, wherein the drain layer comprises a first concentration of the first type dopant.

14. The method for fabricating a FinFET device according to claim 13, wherein the drift layer comprises a second concentration of the first type dopant, the first concentration is greater than the second concentration.

15. The method for fabricating a FinFET device according to claim 14, wherein the doped-well layer comprises a third concentration of a second type dopant.

16. The method for fabricating a FinFET device according to claim 15, wherein the body layer comprises a fourth concentration of the second type dopant.

17. The method for fabricating a FinFET device according to claim 16, wherein the source layer comprises a fifth concentration of the first type dopant, the fifth concentration is greater than the second concentration.

18. The method for fabricating a FinFET device according to claim 17, wherein the insulating layer comprises silicon nitride, silicon dioxide or a mixture of silicon nitride and silicon dioxide.

19. The method for fabricating a FinFET device according to claim 18, wherein the first type dopant comprises an n-type dopant and the second type dopant comprises a p-type dopant.

20. The method for fabricating a FinFET device according to claim 18, wherein the first type dopant comprises a p-type dopant and the second type dopant comprises an n-type dopant.
